(19) United States
(12) Patent Application Publication
(10) Pub. No.: US 2003/0160264 A1
(43) Pub. Date: Aug. 28, 2003

(54) Hetero-junction semiconductor device and manufacturing method thereof

(75) Inventors: Shigeru Yagi, Minamiashigara-shi (JP); Seiji Suzuki, Minamishigara-shi (JP)

Correspondence Address: OLIFF & BERRIDGE, PLC, P.O. BOX 19928, ALEXANDRIA, VA, 22320, US

(73) Assignee: FUJI XEROX CO., LTD., Tokyo (JP)

(21) Appl. No.: 10/217,036

(22) Filed: Aug. 13, 2002

(30) Foreign Application Priority Data
Feb. 22, 2002 (JP) 2002-046835

(51) Int. Cl. H01L 31/0328; H01L 31/0336; H01L 31/072; H01L 31/109

(52) U.S. Cl. 257/183

(57) ABSTRACT

A hetero-junction semiconductor device is used as a diode in which a compound semiconductor layer at least contains one or more elements selected from group IIIA elements and one or more elements selected from group VA elements. The compound semiconductor layer is laminated on a surface of a heterogeneous semiconductor having a different conduction type from that of the compound semiconductor.

### BACKGROUND OF THE INVENTION

1. Field of the Invention

This invention concerns a hetero-junction semiconductor device in which a heterogenuous semiconductor layer is laminated on a surface of a semiconductor, as well as a manufacturing method thereof.

2. Description of Related Art

Since hetero-pn-junction devices including, in combination, p-type and n-type semiconductors of different energy gaps can provide characteristics not found in homo-pn-junctions including, in combination, homogeneous semiconductors having an identical energy gap, many studies have been conducted for them. However, since the heterojunction semiconductor includes a junction of two different semiconductors and their lattice constants are different from each other, dangling bonds are formed at the boundary between the semiconductors to form localized state levels. Particularly, when a high temperature is required for forming a semiconductor layer on another semiconductor and when the difference of the thermal expansion coefficient is large between the two semiconductors, large stresses exert after cooling to induce occurrences of bonding defects and cause structural defects such as cracks and peeling at the interface. Generation of such a great amount of localized state levels at the interface degrades the characteristics of the junction and no sufficient characteristics are obtainable as the semiconductor device.

In the hetero-junction semiconductors, since characteristics such as (1) a barrier and confinement effect to carriers, (2) separation of carriers and (3) acceleration or deceleration of carriers, which are difficult to attain in homo-junction semiconductors, it is possible, by employing these characteristics, to provide semiconductor devices having advantageous features such as a high electron mobility transistor and a super high speed operation transistor.

On the other hand, in semiconductor devices at high temperature operation, wide band gap semiconductors undergoing no large effect on the Fermi level by heat have been drawing attention, and formation of a hetero-junction with such a wide gap semiconductor is a key to implementation of semiconductor devices with the advantageous features.

For the wide band gap semiconductors described above, III-nitride compound semiconductors (hereinafter sometimes simply referred to as “nitride semiconductor”) have been drawing attention in recent years. However, the nitride semiconductor is formed using a sapphire substrate at a high temperature of 1000° C. Further, while hetero-junction between the nitride semiconductors can be implemented, for example, in a quantum well structure, hetero-junction with a heterogeneous semiconductor was difficult. Further, crystals of the nitride semiconductors are formed by providing a buffer layer such as of GaN, AlN and ZnO on the boundary with the substrate and it involves a problem that a hetero semiconductor junction cannot be formed directly.

### SUMMARY OF THE INVENTION

That is, this invention provides a hetero-junction semiconductor device which is obtained at a reduced cost and applicable to high performance diodes and transistors. Further, this invention also provides a manufacturing method of a hetero-junction semiconductor device which is stable and less expensive.

This invention provides a hetero-junction semiconductor device in which a compound semiconductor layer at least containing one or more elements selected from group IIIA elements and one or more elements selected from group VA elements is laminated on a surface of a heterogeneous semiconductor having a different conduction type from that of the compound semiconductor.

The hetero-junction semiconductor device described above can be constituted as a diode having diode characteristics, or as a transistor having transistor characteristics

### BRIEF DESCRIPTION OF THE DRAWINGS

Preferred embodiments of this invention will be described in details based on the followings, wherein:

FIG. 1 is an enlarged cross-sectional view illustrating an example for the constitution of a hetero-junction semiconductor device according to this invention;

FIG. 2 is an enlarged cross-sectional view illustrating another example for the constitution of a hetero-junction semiconductor device according to this invention;

FIG. 3 is an enlarged cross-sectional view illustrating still another example for the constitution of a hetero-junction semiconductor device according to this invention; and

FIG. 4 is a schematic constitutional view showing a preferred example of an apparatus for forming a photosemiconductor layer used in this invention.

### DESCRIPTION OF PREFERRED EMBODIMENTS

This invention will be described in details hereinbelow.

The hetero-junction semiconductor device according to this invention uses a hetero-junction semiconductor in which a compound semiconductor layer at least containing one or more elements selected from group IIIA elements and one or more elements selected from group VA elements is laminated on a surface of a heterogeneous semiconductor having a different conduction type from that of the compound semiconductor. The hetero-junction semiconductor device is used as a diode (rectifying device) or a transistor.

<Hetero-Junction Semiconductor>

In the hetero-junction semiconductor used in this invention, a compound semiconductor layer at least containing one or more elements selected from the group IIIA elements and one or more elements selected from the group VA elements is formed in the state of crystals, microcrystasls or polycrystals on a surface of a semiconductor mainly including silicon of p-type or n-type crystalline silicon, microcrystals, polycrystal silicon or amorphous silicon or a semiconductor including one or more elements selected from the group IIIA elements, and P and/or As (heterogeneous semiconductor) to thereby form a hetero-junction. Further, the compound semiconductor layer can be formed on the surface of the heterogeneous semiconductor directly at a low temperature.

The hetero-junction semiconductor used in this invention will be explained by constitution.

-Heterogeneous Semiconductor-

The heterogeneous semiconductors used in this invention have no particular restriction so long as they are heterogeneous semiconductors with the different conduction type from that of the compound semiconductor layer to be described later. Further, the heterogeneous semiconductor in this invention may also serve as a substrate for forming the compound semiconductor layer to be described later. The heterogeneous semiconductors can include semiconductors mainly including silicon, semiconductors including one or more elements selected from the group IIIA elements (group No. 13 according to IUPAC Nomenclature of Inorganic Chemistry, 1989 revised edition) and P and/or As, and substrates including a Cu-containing chalcopyrite type compound. They may be p-conduction type or n-conduction type.

Among them, semiconductors mainly including silicon and semiconductors having one or more elements selected from the group IIIA elements and P and/or As are used preferably in view of easy control of p-type or n-type conductivity and easiness of use as the substrate.

In a case of using semiconductors mainly including silicon as the heterogeneous semiconductors, the silicon is preferably crystalline silicon, polycrystalline silicon, microcrystalline silicon and amorphous silicon. Further, the semiconductors including one or more elements selected from the group IIIA elements and P and/or As can include, for example, GaAs, GaAlAs, GaAlP, GaP, AlGaP, InP, InGaP, InAlP and GaAsN.

Further, as the substrates including the Cu-containing chalcopyrite type compound, p-type chalcopyrite compound semiconductors such as CuInSe₂, CuInS₂, CuGaSe₂ and CuInGaSe₂ can be used, for example.

Further, II-VI compound semiconductors such as ZnO, CdS, CdSe and CdTe can also be used.

In a case where the hetero-junction semiconductor is used as a diode or a transistor as in this invention, the thickness of the heterogeneous semiconductor is preferably within a range from 1.0 to 1000 μm.

-Compound Semiconductor Layer-

The compound semiconductor layer used in this invention contains one or more elements selected from group IIIA elements (group No. 13 according to IUPAC Nomenclature of Inorganic Chemistry, 1989 revised edition) and one or more elements selected from the group VA elements (group No. 15 according to IUPAC Nomenclature of Inorganic Chemistry, 1989 revised edition) and optionally contains other components.

The group IIIA elements can include, specifically, B, Al, Ga, In and Tl and, preferably, it is at least one element selected from Al, Ga and In. Further, the group VA elements can include, N, P, As, Sb and Bi, with nitrogen (N) being particularly preferred.

In the compound semiconductor layer, the relation between the number of atoms m for the group IIIA elements and the number of atoms n for the group VA elements preferably satisfies the following relation (1):

0.5/1.0≦m/n≦1.0/0.5 (1)

When m/n is out of this range, since a portion taking tetra hedral type bonding is decreased in the bonding between the group IIIA elements and nitrogen, defects are increased and it may not function as a semiconductor satisfactorily.

The compound semiconductor layer formed on the surface of the heterogeneous semiconductor may be any of single crystals, amorphous, microcrystals or polycrystals. In the case of microcrystals or polycrystals, since they include many defects such as bonding defects dislocation defects, and defects at the crystal grain boundary, inactivation with hydrogen or halogen elements in the film is necessary. The hydrogen or hydrogen elements are taken into defects such as bonding defects or defects at the crystal grain boundaries to conduct electric compensation. Accordingly, traps concerning diffusion or transport of carriers are eliminated and they can exhibit excellent electric characteristics. To obtain a state where hydrogen or halogen elements in the crystals are contained in the film, it is preferred that the compound semiconductor layer is formed at a low temperature of 600° C. or lower including the film formation and subsequent steps.

The compound semiconductor layer used in this invention contains hydrogen preferably within a range from 0.1 to 40 atomic %. If the hydrogen contained in the compound semiconductor layer is less than 0.1 atomic %, it is insufficient to eliminate bonding defects at the crystal grain boundary or bonding defects or unbending sites inside the amorphous phase boundary by the bonding with hydrogen to inactivate the defective energy level formed in the band, and the bonding defects or structural defects are sometimes increased.

On the contrary, when hydrogen in the compound semiconductor layer exceeds 40 atomic %, a probability that two or more hydrogen atoms are bonded to the group IIIA elements and nitrogen is increased whereby the elements no more retain the 3-dimensional structure but form 2-dimensional and chain-like networks and, particularly, generate a great amount of voids at the crystal grain boundary, so that an additional energy level is formed in the band to deteriorate the electric characteristics and lower the mechanical property such as hardness. Further, the compound semiconductor layer tends to be oxidized and, as a result, a great amount of impurity defects are caused in the compound semiconductor layer and no satisfactory electrical characteristics can be obtained.

Further, when hydrogen in the compound semiconductor layer exceeds 40 atomic %, since hydrogen inactivates dopants that are doped for controlling the electric characteristics, a compound semiconductor layer formed of electrically active amorphous or microcrystals cannot be obtained.

The amount of hydrogen can be measured for the absolute value by hydrogen forward scattering (HFS), or can be estimated by IR absorption spectroscopy.

The compound semiconductor layer may be amorphous, microcrystalline or polycrystalline as described above. The crystal system may be a tetragonal system which may be mixed with a hexagonal system, or may be any one of them. The face orientation may be plural but it is desirably of a single type. Further, the growing cross section may be of a columnar structure or of smooth crystals.

The single crystals mean those mainly including bright spots, those of not ring-like diffraction pattern but of substantially or essentially spotwise shape and, further, those of a streak shape in transmission electron diffractiometry pattern or reflection electron diffractiometry, or further those where one face orientation includes 80% or more of the entire strength in the X-ray diffractiometry.

In a case where the hetero-junction semiconductor is used as a diode or transistor as in this invention, the thickness of the compound semiconductor layer is preferably within a range from 0.05 to 10 μm.

-Hetero-Junction Semiconductor-

The hetero-junction semiconductor using the heterogeneous semiconductor and the compound semiconductor layer, in a case of using the silicon substrate as the heterogeneous semiconductor, for example, can be obtained by forming the compound semiconductor layer directly on the surface and forming a hetero-semiconductor junction relative to the silicon substrate.

For example, a p-type compound semiconductor layer is formed on the surface of the n-type silicon substrate while an n-type compound semiconductor is formed on the p-type silicon substrate. Thus, a junction of different band gaps is formed at the boundary between the silicon layer and the compound semiconductor layer to form a high diffusion potential, making it possible to obtain an excellent rectifying characteristic or large amplifying performance. Further, i-type silicon or an i-type compound semiconductor layer may be disposed as an intermediate conduction type between the p-type silicon substrate and the n-type compound semiconductor layer with an aim of further effectively conducting current transportation and barrier inhibition of the semiconductor junction device.

More specifically, for p-type silicon, n-type Al_{X1}Ga_{Y1}N/n⁺Al_{X2}Ga_{Y2}N, i-type Al_{X1}Ga_{Y1}N/n-type Al_{X2}Ga_{Y2}N, n-type GaN/n⁺-type GaN, and n-type GaInN/n⁺GaAlN can be laminated. Further, difference between the Fermi energy and the conduction band energy can be increased. Further, for n-type silicon, i-type Ga_{X1}In_{Y1}N/p-type Ga_{X2}In_{Y2}N, p-type Ga_{X1}In_{Y1}N/p⁺-type Ga_{X2}In_{Y2}N, p-type GaIn/p-type GaN, and p-type GaInN/p⁺-type GaAlN can be laminated in combination. With such a constitution, favorable a junction can be prepared with no barrier at the boundary of respective active layers. X1, Y1 and X2, Y2 represent compositional ratios which are indicated by a numerical values each within a range from 0 to 1.0.

The same constitution is also possible in a case where microcrystals, polycrystals and amorphous silicon are used as the heterogeneous semiconductor.

The nitride semiconductor is a semiconductor of a wide band gap as compared with the heterogeneous semiconductor bonded therewith. However, for selecting the relation of the bonding energy for the active portion between both of the semiconductor junction portions, it may be a nitride semiconductor including, for example, Al and/or Ga, and nitrogen, or In may also be incorporated in addition to Al and Ga. The concentration of incorporated In is preferably within a range: 0<In/(Al+Ga+In)<0.1.

The crystalline, microcrystalline or polycrystalline compound semiconductor layer forming the hetero-junction to the p-type heterogeneous semiconductor preferably contains one or more elements selected from the IVA group elements. Further, a crystalline, microcrystalline or polycrystalline compound semiconductor layer forming a hetero-junction relative to the n-type heterogeneous semiconductor preferably contains one or more elements selected from group II elements.

The group IVA elements can include C, Si, Ge, Sn and Pb. Among them, C, Si, Ge and Sn are preferably contained. Then, when a hetero-junction is formed with the compound semiconductor layer relative to the p-type heterogeneous semiconductor, the doping amount of one or more elements selected from C, Si, Ge and Sn can be controlled to change the Fermi energy along with the change of the band gap, such that band barriers are not formed in the conduction band or the valence band continuously.

Further, the group II elements can include Be, Mg, Ca, Sr, Ba, Ra, Zn and Cd. Among them, Be, Mg, Ca, Zn and Sr can be contained preferably. Then, when the hetero junction is formed by the compound semiconductor layer relative to the n-type heterogeneous semiconductor, the doping amount of one or more elements selected from Be, Mg, Ca, Zn and Sr can be controlled to change the Fermi energy along with the change of the band gap, such that band barriers are not formed in the conduction band or the valence band continuously.

<Method of Preparing Hetero-Junction Semiconductor>

The hetero-junction semiconductor can be manufactured as described below. However, the manufacturing method is not restricted thereto. In the following manufacturing method, explanation will be made for an example of using at least one element selected from Al, Ga, In as the group IIIA element of the compound semiconductor layer and using nitrogen as the group VA element.

FIG. 4 is a schematic constitutional view of an apparatus for forming a compound semiconductor layer in this invention in which plasmas are used as an activation unit.

In FIG. 4 are shown a chamber 1 capable of evacuation, an exhaust port 2, a substrate holder 3, a heater 4 for heating the substrate, quartz tubes 5 and 6 connected with the chamber 1, which are in communication with gas introduction pipes 9 and 10 respectively. Further, a gas introduction tube 11 is connected with the quartz tube 5 while a gas introduction tube 12 is connected with the quartz tube 6.

In this apparatus, an N₂ gas is used, for example, as a nitrogen source and introduced from the gas introduction tube 9 to the quartz tube 5. Then, microwaves at 2.45 GHz are supplied to a microwave guide tube 8 connected, for example, to a microwave oscillator (not illustrated) using a magnetron to cause electric discharging in the quartz tube 5. On the other hand, an H₂ gas, for example, is introduced from another gas introduction tube 10 into the quartz tube 6. Then, radio frequency waves at 13.56 MHz are supplied from a radio frequency oscillator (not illustrate) to radio frequency coils 7 to cause electric discharging in the quartz tube 6. Further, by introducing, for example, trimethyl gallium by the gas introduction tube 12 disposed at the downstream to the discharging space, an amorphous or microcrystalline unsingle crystal gallium nitride semiconductor can be formed on the surface of the substrate set to the substrate holder 3.

In this case, the heterogeneous semiconductor mainly formed of silicon may be set as it is as the substrate on the substrate holder 3, or a heterogeneous semiconductor may be formed to the surface of another substrate and the substrate may be set to the substrate holder 3.

Which of amorphous, microcrystals, polycrystals highly oriented and grown into a columnar shape or single crystals are formed is determined depending on the kind of the substrates, the substrate temperature, the flow rate and the pressure of gas and the discharging condition. The substrate temperature is preferably from 100° C. to 600° C., and the compound semiconductor layer is preferably formed on the surface of the heterogeneous semiconductor at a temperature of 600° C. or lower.

As described above, when a nitride semiconductor layer is formed on the surface of a silicon substrate or the like, since it is usually conducted at a high temperature of 1000° C., there has been a problem that cracks occur in the nitride semiconductors layer after cooling due to a difference of the thermal expansion coefficient between silicon and nitride semiconductor. However, since the layer can be formed in this invention at a relatively low temperature of 600° C. or lower, such a problem does not occur and the film can be formed uniformly.

Further, in the existent film formation method described above, it is necessary to provide a buffer layer on the surface of the silicon substrate and a nitride semiconductor layer or the like has to be formed on the surface thereof by the reason described above even when silicon is simply used as a substrate. In this invention, since there is no problem in the film formation property, the compound semiconductor layer can be formed directly on the surface of the heterogeneous semiconductor. Then, a hetero-junction free from structural defects can be formed between the nitride semiconductor and the heterogeneous semiconductor.

In a case where the substrate temperature is high and/or the flow rate of the material gas of the group IIIA element is small, the structure tends to form microcrystals or single crystals. For example, when the flow rate of the starting gas of the IIIA element is small even when the substrate temperature is 300° C. or lower, the structure tends to be crystalline, and when the substrate temperature is 300° C. or higher, the structure tends to be also crystalline in a case where the flow rate of the material gas of group IIIA element is larger than that under lower temperature condition. Further, when H₂ discharging is conducted, for example, crystallization can be proceeded further than in the case of not conducting discharging.

An organic metal compound containing indium or aluminum may also be used instead of trimethyl gallium described above, or they may be mixed. Further, such organic metal compounds may be introduced separately from the gas introduction tube 11.

As the starting material for the group IIIA element in the compound semiconductor layer, an organic metal compound containing one or more elements selected from Al, Ga and In can be used.

As the organic metal compounds described above, liquids or solids, for example, of trimethyl aluminum, triethyl aluminum, tertiarybutyl aluminum, trimethyl gallium, triethyl gallium, tertiarybutyl gallium, trimethyl indium, triethyl indium, tertiarybutyl indium can be used singly or in admixture after evaporation under bubbling with a carrier gas. As the carrier gas, a rare gas such as He or Ar, a single element gas such as H₂ or N₂, hydrocarbon such as methane or ethane or halogenated hydrocarbon such as CF₄ or C₂F₆ may be used.

As the nitrogen starting material, gas or liquid of N₂, NH₃, NF₃, N₂H₄ and methyl hydrazine can be used after evaporation or by bubbling with a carrier gas.

In the compound semiconductor layer, elements for p, n control can be doped into the film. The n-type doping elements can include Li in group IA (group No. 1 according to IUPAC Nomenclature of Inorganic Chemistry, 1989 revised edition); Cu, Ag, Au in group IB (group No. 11 according to IUPAC Nomenclature of Inorganic Chemistry, 1989 revised edition); Mg in group IIA (group No. 2 according to IUPAC Nomenclature of Inorganic Chemistry, 1989 revised edition); Zn in group IIB (group No. 12 according to IUPAC Nomenclature of Inorganic Chemistry, 1989 revised edition); Si, Ge, Sn, Pb in group IVA (group No. 14 according to IUPAC Nomenclature of Inorganic Chemistry, 1989 revised edition); and S, Se and Te in group VIA (group No. 16 according to IUPAC Nomenclature of Inorganic Chemistry, 1989 revised edition).

The p-type doping elements can include Li, Na, K in group IA; Cu, Ag, Au in group IB; Be, Mg, Ca, Sr, Ba, Ra in group IIA; Zn, Cd, Hg in group IIB C, Si, Ge, Sn, Pb in group IVA; S, Se, Te in group VIA (group No. 16 according to IUPAC Nomenclature of Inorganic Chemistry, 1989 revised edition); Cr, Mo, W in group VIB (group No. 6 according to IUPAC Nomenclature of Inorganic Chemistry, 1989 revised edition); and Fe (group No. 8 according to IUPAC Nomenclature of Inorganic Chemistry, 1989 revised edition), Co (group No. 9 according to IUPAC Nomenclature of Inorganic Chemistry, 1989 revised edition) and Ni (group No. 10 according to IUPAC Nomenclature of Inorganic Chemistry, 1989 revised edition) in group VIII.

Among them, Si, Ge and Sn are particularly preferred as the n-type element, while Be, Mg, Ca, Zn and Sr are preferred the p-type element.

Upon doping, SiH₄, Si₂H₆, GeH₄, GeF₄ or SnH₄ can be used for n-type, while BeH₂, BeCl₂, BeCl₄, cyclopentadienyl magnesium, dimethyl calcium, dimethyl strontium, dimethyl zinc or diethyl zinc can be used for i-type and p-type in a gas state. Further, for doping such elements into film, known methods such as thermal diffusion and ion injection may be adopted.

Specifically, an amorphous or microcrystalline nitride semiconductor of optional conduction type such as n-type or p-type can be obtained by introducing a gas containing at least one of elements selected from C, Si, Ge and Sn or a gas containing at least one of elements selected from Be, Mg, Ca, Zn and Sr from the downstream to the discharging space (gas introduction tube 11 or gas introduction tube 12). In a case of introducing the C element among the elements described above, carbon of the organic metal compound may also be used depending on the conditions.

In the apparatus described above, the active nitrogen or active hydrogen formed by the discharging energy can be controlled independently, or a gas containing together nitrogen atoms and hydrogen atoms such as NH₃ may also be used. Further, a hydrogen gas may also be added. Further, a condition of liberating to form active hydrogen from an organic metal compound may also be adopted. With these procedures, since activated atoms of the group III and nitrogen atoms are present under the controlled state on the surface of the substrate and the hydrogen atoms convert methyl groups and ethyl groups into inactive molecules such as methane and ethane, an amorphous or microcrystalline film substantially or quite free from carbon and with restrained film defects can be formed even at a low temperature.

In the apparatus described above, the activation unit may adopt high frequency discharging microwave discharging, or an electro cyclotron resonance system or a helicon plasma system, which may be used alone or two or more of them may be used. Further, while the high frequency discharging and the microwave discharging are used in FIG. 4, both of the two units may be microwave discharging or high frequency discharging. Furthermore, the electro cyclotron resonance system or the helicon plasma systems may be used for both of the two units. In a case of the high frequency discharging, the high frequency oscillator may be an induction type or a capacitance type. The frequency in this case is preferably 50 KHz to 100 MHz.

In a case of using different activation units (excitation units), it is necessary that electric discharging can be generated simultaneously under an identical pressure, and a pressure difference may be made between the discharging portion and the film formation portion (in the chamber 1). Further, in a case of conducting activation under an identical pressure, when different activation units (excitation units), for example, the microwave oscillator and the high frequency oscillator are used, the excitation energy for excited species can be changed greatly, which is effective for the control of the film quality.

Further, the compound semiconductor layer used in this invention can also be formed in an atmosphere in which at least hydrogen is activated such as in reactive vacuum deposition, ion plating or reactive sputtering. In addition, a metal organic chemical vapor deposition method or molecular beam epitaxy may also be used, and simultaneous use of active nitrogen or active hydrogen is effective. Further, it is possible to conduct hydrogenation by hydrogen plasmas or hydrogen ions after film formation.

<Hetero-Junction Semiconductor Device>

As described above, a hetero semiconductor junction is formed between the crystalline, microcrystalline or polycrystalline compound semiconductor and the p-type or n-type heterogeneous semiconductor. Then, an excellent diode characteristic or transistor characteristic can be obtained by the hetero semiconductor junction portion.

In this invention, the hetero-junction semiconductor having the characteristic described above is used as the hetero-junction semiconductor device such as a diode or a transistor. When external voltage is applied in the hetero junction semiconductor device, a flowing current may be transportation of electrons or holes or transportation of both of them. Further, in the hetero-junction semiconductor, when junction is performed by a semiconductors having an intermediate band gap, current transportation and inhibition by a barrier of the semiconductor device can be conducted even more effectively.

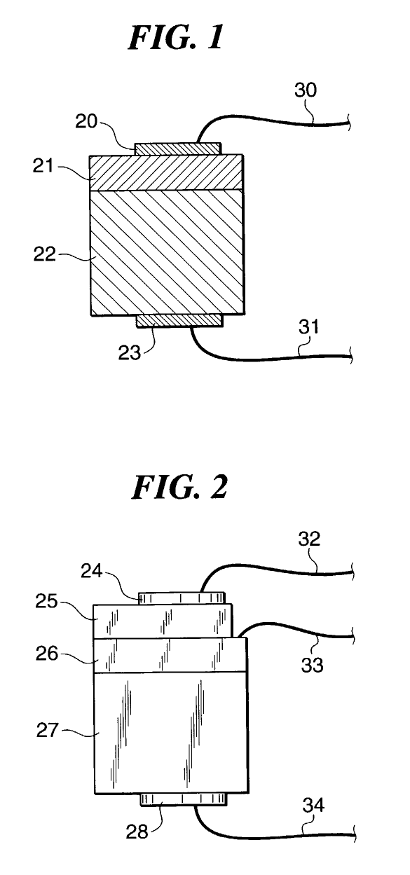

FIG. 1 is an enlarged cross-sectional view showing an example of a hetero-junction semiconductor device used as the diode of this invention. In FIG. 1 are shown an electrode 20, a compound semiconductor layer 21, a heterogeneous semiconductor 22, an electrode 23 and wires 30, 31.

The hetero-junction semiconductor device used as the diode in FIG. 1 is manufactured, for example, by forming an n-type nitride semiconductor layer as the compound semiconductor 21 to a thickness of 0.05 to 10 μm on the surface of a p-type silicon substrate as the heterogeneous semiconductor 22 and disposing the electrodes 20, 23 on the surfaces of the silicon substrate and the nitride semiconductor layer opposite to the junction portions respectively. For application of external voltage, the electrodes 20, 23 have to be formed in ohmic contact with the surface of the silicon substrate and the nitride semiconductor, respectively. Accordingly, it is preferred to use Au, Ni, Al or Ag for the electrodes 20, 23 and dispose them each to a thickness of 0.1 to 5 μm by vacuum deposition or sputtering.

FIG. 2 is an enlarged cross-sectional view showing an example of a hetero-junction semiconductor device used as a bipolar transistor in this invention. In FIG. 2 are shown an electrode 24, a compound semiconductor layer 25, heterogeneous semiconductors 26, 27, an electrode 28, and wires 32, 33 and 34. Further, the compound semiconductor layer 25 is used as an emitter, the heterogeneous semiconductor 26 is used as a base and the heterogeneous semiconductor 27 is used as a collector.

The hetero-junction semiconductor device used as the transistor shown in FIG. 2 is prepared, for example, by at first conducting doping to the surface of the p-type silicon substrate as the heterogeneous the semiconductor 27 to form a surface layer portion of 0.1 μm in thickness as a p⁺-type silicon heterogeneous semiconductor 26, then forming a nitride semiconductor layer to a thickness of 0.05 to 0.5 μm as the compound semiconductor layer 26 on the surface thereof and then disposing the electrodes 24, 28 in the same manner as described above. In this case, the base and the emitter may also be formed with a nitride semiconductor layer (compound semiconductor layer).

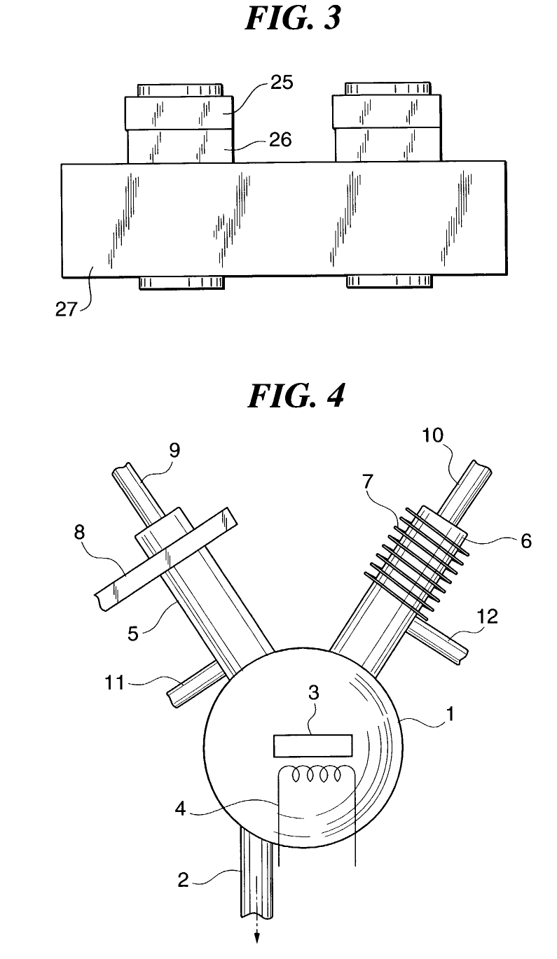

FIG. 3 is an enlarged cross-sectional view of a hetero-junction semiconductor device in which plural hetero semiconductor junction devices used as the transistor in FIG. 2 are formed on one identical collector substrate. In FIG. 3, the constitution of the device is identical with that in FIG. 2 except that heterogeneous semiconductors 27 are identical. By integrating plural devices on one identical substrate as described above, a function as a circuit can be obtained. In this case, the plural devices formed on the surface of the identical substrate may be constituted only of diodes or only of transistors. Further, it may include a combination of a diode and a transistor.

In a case of forming the plural hetero-junction semiconductor devices on the surface of the identical substrate shown in FIG. 3, since the compound semiconductor layer 25 used in this invention can be formed at a temperature of 600° C. or lower, the plural devices can be manufactured simultaneously, for example, by using a mask formed with plural apertures.

As described above, in this invention, a favorable hetero-junction can be formed by forming the compound semiconductor layer by a film formation method by low temperature growing including hydrogen to inactivate bonding defects at the junction boundary relative to the heterogeneous semiconductor and prevent occurrences of defects after film formation due to the difference of each other's thermal expansion coefficients. Then, the heterojunction semiconductor device having the nitride semiconductor layer (compound semiconductor layer) formed on the surface of the heterogeneous semiconductor can be applied to high voltage and high power use and can be used as diodes and transistors of excellent light fastness, heat resistance and oxidation resistance.

Preferred embodiments of this invention are as shown below.

Compound semiconductor layers at least containing one or more elements selected from the group IIIA elements and one or more elements selected from group VA elements may be plurally laminated on a surface of a heterogeneous semiconductor having a different conduction type from that of the compound semiconductor.

The compound semiconductor layer may contain 0.1 to 40 atomic % of hydrogen and/or halogen elements.

The compound semiconductor layer may contain one or more elements selected from group IVA elements and may be formed on a surface of a p-type semiconductor layer.

The compound semiconductor layer may contain one or more elements selected from group II elements and may be formed on a surface of an n-type semiconductor layer.

The heterogeneous semiconductor may be a semiconductor mainly including silicon.

The heterogeneous semiconductor may include one or more elements selected from the group IIIA elements, P and/or As.

The silicon may be crystalline silicon, polycrystalline silicon, microcrystalline silicon or amorphous silicon.

The compound semiconductor layer may be formed at a temperature of 600° C. or lower.

The compound semiconductor layer may be formed directly on a surface of the heterogeneous semiconductor.

### EXAMPLE

This invention is to be described specifically with reference to examples but the invention is not restricted to such examples.

### Example 1

-Preparation of Hetero-Junction Semiconductor Device-

Ag was vacuum-deposited to 0.1 μm in thickness to provide an ohmic contact electrode on one surface of a p-type silicon substrate (10×10 mm, 350 μm in thickness) etched with an aqueous solution of hydrogen fluoride at a concentration of 10 mass %, having a resistivity of 20 Ωcm and face orientation (100). The silicon substrate was placed to the substrate holder 3 of the apparatus shown in FIG. 4. The surface opposite to the surface with the electrode was directed to the gas introduction tube and, after evacuating the inside of the chamber 1 by way of the exhaust port 2, the substrate was heated to 300° C. by the heater 4. Then, an N₂ gas was introduced at 2000 sccm from the gas introduction tube 9 into the quartz tube 5 of 25 mm in diameter. The output of the microwaves at 2.45 GHz was set to 250 W by way of the microwave guide tube 8 and discharging was conducted while taking matching by a tuner. The power of the reflection waves in this case was at 0 W. An H₂ gas was introduced at 500 sccm from the gas introduction tube 10 to the quartz tube of 30 mm in diameter. When the output of the radio frequency power at 13.5 MHz was set to 100 W, the power of the reflection waves was at 0 W.

In this state, vapors of trimethyl gallium (TMGa) kept at 0° C. were introduced at 1 sccm through a mass flow controller from the gas introduction tube 12 at a pressure of 10⁶ Pa under bubbling using hydrogen as a carrier gas. Then, hydrogen-diluted silane was introduced so as to provide 1 atomic % from the gas introduction tube 12. In this case, the reaction pressure measured by a Baratron vacuum gauge was 65 Pa.

Film formation was conducted for 60 minutes in the state described above, and an n-type Si doped GaN:H film of 0.1 μm in thickness was formed directly on the surface of the silicon substrate. When the hydrogen composition in the n-type Si doped GaN:H film was measured by HFS (Hydrogen Forward Scattering), it was 5 atomic %. Further, the optical gap of the film was 3.2 eV, and lights at wavelength longer than 380 nm were completely transmitted.

An Au electrode of 3 mm in diameter was vapor-deposited to a thickness of 0.1 μm on the surface of the n-type Si doped GaN:H film to manufacture a hetero-junction semiconductor device.

-Evaluation-

When the current/voltage characteristic of the hetero-junction semiconductor device was measured, a current rectifying characteristic was recognized between the forward direction and the backward direction. In this case, the forward/backward current ratio within a range of ±2V to ±4V was about 500 to 1000 times showing that it exhibited a sufficient diode characteristic. Further, when an sinusoidal alternating current at ±5V at a frequency of 1 kHz was introduced to the hetero-junction semiconductor device, a half-wave rectified alternating current was obtained at the output and it was found that the device could be used effectively as a diode.

The result shows that the n-type Si doped GaN:H film forms a hetero-pn-junction with p-type silicon and has an excellent function as a semiconductor device. It has also been found that a hetero-junction transistor can be manufactured by use of an np-type silicon as a substrate and forming the n-type Si-doped GaN:H film to the surface thereof by utilizing the foregoings.

### Example 2

-Manufacture of Hetero-Junction Semiconductor Device-

An n-type Si-doped AlGaN:H layer was formed directly on the surface of the p-type silicon substrate using the same silicon substrate as that used in Example 1, except for introducing trimethyl aluminum kept at 20° C. so as to provide a ¼ amount relative to Ga in addition to trimethyl gallium(TMGa) in Example 1. The hydrogen composition in the Si-doped AlGaN:H film (compositional ratio: Al_{0.2}Ga_{0 8}N) was the same as that in Example 1. When the X-ray diffraction pattern for the AlGaN:H film formed on the surface of the silicon substrate was measured, it was found that the (0001) face of the hexagonal system was grown.

An Au electrode of 3 mm in diameter was deposited to 0.1 μm in thickness on the surface to manufacture a hetero-junction semiconductor device.

-Evaluation-

When the current/voltage characteristic was measured for the hetero-junction semiconductor device in the same manner as in Example 1, a current rectifying property was found between the forward direction and the backward direction. The forward/backward current ratio in a range from ±2V to ±4V was 500 to 1000 times and it was found that the device exhibited a sufficient diode characteristic. Further, when a sinusoidal alternating current at ±5V at a frequency of 1 kHz was introduced to the hetero-junction semiconductor device, it was found that a half-wave rectified alternating current was obtained as an output and the device could be used effectively as the diode.

This result shows that the n-type Si doped AlGaN:H film forms a hetero-pn-junction with p-type silicon and has an excellent function. Further, it has also been found that a heterojunction transistor can be manufactured by use of the np-type silicon as a substrate and forming the n-type AlGaN:H film to the surface by utilizing the foregoings.

### Example 3

-Manufacture of Hetero-Junction Semiconductor Device-

A cleaned p-type GaAs substrate (5×5 mm, 200 μm in thickness) of (100) face orientation was used and an n-type Si doped GaN:H film was formed on the surface thereof in the same manner as in Example 1. An Au electrode of 2 mm in diameter was vapor-deposited to 0.1 μm in thickness on the surface thereof to manufacture a hetero-junction semiconductor device.

-Evaluation-

When the current/voltage characteristic was measured for the hetero-junction semiconductor device in the same manner as in Example 1, a current rectifying property was found between the forward direction and the backward direction. The forward/backward current ratio in a range from ±2V to ±4V was 500 to 1000 times and it was found that the device exhibited a sufficient diode characteristic. Further, when a sinusoidal alternating current at ±5V at a frequency of 1 kHz was introduced to the heterojunction semiconductor device, it was found that a half-wave rectified alternating current was obtained as an output and the device could be used effectively as the diode.

This result shows that the n-type Si doped AlGaN:H film forms a hetero-pn-junction with p-type GaAs and has an excellent function. Further, it has also been found that the hetero-junction transistor can be manufactured by use of the np-type silicon as a substrate and forming the n-type AlGaN:H film described above to the surface by utilizing the foregoings.

This invention can provide a hetero-junction semiconductor device that can be used as a high performance diode, transistor and the like at a reduced cost. Further, this invention can provide a method of manufacturing a stable and inexpensive hetero-junction semiconductor device.

The entire disclosure of Japanese Patent Application No. 2002-46835 filed on Feb. 22, 2002 including specification, claims, drawings and abstract is incorporated herein by reference in its entirety.

What is claimed is:

1. A heterojunction semiconductor device comprising a compound semiconductor layer at least containing one or more elements selected from group IIIA elements and one or more elements selected from group VA elements; and a heterogeneous semiconductor having a different conduction type from that of the compound semiconductor, the compound semiconductor layer being disposed on a surface of the heterogeneous semiconductor.

2. The hetero-junction semiconductor device according to claim 1, wherein compound semiconductor layers at least containing one or more elements selected from the group IIIA elements and one or more elements selected from the group VA elements are plurally laminated on the surface of the heterogeneous semiconductor having a different conduction type from that of the compound semiconductor.

3. The hetero-junction semiconductor device according to claim 1, wherein the compound semiconductor layer contains 0.1 to 40 atomic % of hydrogen and/or halogen elements.

4. The hetero-junction semiconductor device according to claim 1, wherein the compound semiconductor layer contains one or more elements selected from group IVA elements and is formed on a surface of a p-type semiconductor layer.

5. The hetero-junction semiconductor device according to claim 1, wherein the compound semiconductor layer contains one or more elements selected from group II elements and is formed on a surface of an n-type semiconductor layer.

6. The hetero-junction semiconductor device according to claim 1, wherein the heterogenuous semiconductor is a semiconductor mainly comprising silicon.

7. The hetero-junction semiconductor device according to claim 1, wherein the heterogenuous semiconductor comprises one or more elements selected from the group IIIA elements, P and/or As.

8. The heterojunction semiconductor device according to claim 6, wherein the silicon is crystalline silicon, polycrystalline silicon, microcrystalline silicon or amorphous silicon.

9. The heterojunction semiconductor device according to claim 1, having a diode characteristic.

10. The hetero-junction semiconductor device according to claim 2, having a transistor characteristic.

11. A method of manufacturing a hetero-junction semiconductor device comprising a compound semiconductor layer at least containing one or more elements selected from group IIIA elements and one or more elements selected from group VA elements, and a heterogeneous semiconductor having a different conduction type from that of the compound semiconductor, the compound semiconductor layer being disposed on a surface of the heterogeneous semiconductor, the method comprising the steps of:
heating the heterogeneous semiconductor to 600° C. or lower; and
forming the compound semiconductor layer on the surface of the heterogeneous semiconductor.

12. The method of manufacturing a hetero-junction semiconductor device according to claim 11, wherein the compound semiconductor layer is formed directly on the surface of the heterogeneous semiconductor.
